(19) United States
(12) Patent Application Publication
(10) Pub. No.: US 2026/0323838 A1
(43) Pub. Date: Oct. 15, 2026

(54) WIRING SUBSTRATE

(71) Applicant: IBIDEN CO., LTD., Gifu (JP)

(72) Inventor: Shigeto IYODA, Gifu (JP)

(73) Assignee: IBIDEN CO., LTD., Gifu (JP)

(21) Appl. No.: 19/311,419

(22) Filed: Aug. 27, 2025

(30) Foreign Application Priority Data
Aug. 28, 2024 (JP) 2024-146880

(51) Int. Cl. H05K 1/185; H05K 1/11; H05K 3/46

(52) U.S. Cl. CPC H05K 1/185; H05K 1/116; H05K 3/4697; H05K 2201/0338; H05K 2201/09481; H05K 2201/09527; H05K 2201/0959

(57) ABSTRACT

A wiring substrate includes a multilayer core substrate, a build-up layer, and components including a first component and a second component. The first component has a first electrode surface and a first non-electrode surface. The second component has a second electrode surface and a second non-electrode surface. The multilayer core substrate includes a central insulating layer, a first resin substrate, a first outer insulating layer, a first surface conductor layer, a first connection conductor, a second resin substrate, a second outer insulating layer, a second surface conductor layer, a second connection conductor, and a through-hole conductor, the first non-electrode surface is positioned on the first surface of the central insulating layer, the first electrode surface is connected to the first connection conductor, the second non-electrode surface is positioned on the second surface of the central insulating layer, and the second electrode surface is connected to the second connection conductor.

### CROSS-REFERENCE TO RELATED APPLICATIONS

The present application is based upon and claims the benefit of priority to Japanese Patent Application No. 2024-146880, filed Aug. 28, 2024, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2015-185564 describes a printed wiring board including a substrate. The entire contents of this publication are incorporated herein by reference.

### SUMMARY OF THE INVENTION

According to one aspect of the present invention, a wiring substrate includes a multilayer core substrate, a build-up layer formed on the multilayer core substrate and including an insulating layer and a conductor layer, and components accommodated in the multilayer core substrate and including a first component and a second component such that the first component has a first electrode surface and a first non-electrode surface on the opposite side with respect to the first electrode surface and that the second component has a second electrode surface and a second non-electrode surface on the opposite side with respect to the second electrode surface. The multilayer core substrate includes a central insulating layer, a first resin substrate formed on a first surface of the central insulating layer, a first outer insulating layer formed on the first resin substrate, a first surface conductor layer formed on the first outer insulating layer, a first connection conductor formed in the first outer insulating layer, a second resin substrate formed on a second surface of the central insulating layer, a second outer insulating layer formed on the second resin substrate, a second surface conductor layer formed on the second outer insulating layer, a second connection conductor formed in the second outer insulating layer, and a through-hole conductor formed through the first outer insulating layer, the first resin substrate, the central insulating layer, the second resin substrate and the second outer insulating layer, the through-hole conductor includes a first via conductor formed in the first outer insulating layer and connecting the first surface conductor layer and the first cover conductor, a second via conductor formed in the second outer insulating layer and connecting the second surface conductor layer and the second cover conductor, an inner wall conductor layer formed on an inner wall of a through hole penetrating through the first resin substrate, the central insulating layer and the second resin substrate, a first cover conductor formed on the first resin substrate, and a second cover conductor formed on the second resin substrate, and the components are positioned such that the first non-electrode surface of the first component is positioned on the first surface of the central insulating layer, the first electrode surface of the first component is connected to the first connection conductor in the first outer insulating layer, the second non-electrode surface of the second component is positioned on the second surface of the central insulating layer, and the second electrode surface of the second component is connected to the second connection conductor of the second outer insulating layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a wiring substrate according to an embodiment of the present invention;

FIG. 2 is an enlarged view of a portion (II) of FIG. 1;

FIG. 3A is a cross-sectional view schematically illustrating a method for manufacturing a wiring substrate according to an embodiment of the present invention;

FIG. 3B is a cross-sectional view schematically illustrating a method for manufacturing a wiring substrate according to an embodiment of the present invention;

FIG. 3C is a cross-sectional view schematically illustrating a method for manufacturing a wiring substrate according to an embodiment of the present invention;

FIG. 3D is a cross-sectional view schematically illustrating a method for manufacturing a wiring substrate according to an embodiment of the present invention;

FIG. 3E is a cross-sectional view schematically illustrating a method for manufacturing a wiring substrate according to an embodiment of the present invention;

FIG. 3F is a cross-sectional view schematically illustrating a method for manufacturing a wiring substrate according to an embodiment of the present invention;

FIG. 3G is a cross-sectional view schematically illustrating a method for manufacturing a wiring substrate according to an embodiment of the present invention;

FIG. 3H is a cross-sectional view schematically illustrating a method for manufacturing a wiring substrate according to an embodiment of the present invention;

FIG. 3I is a cross-sectional view schematically illustrating a method for manufacturing a wiring substrate according to an embodiment of the present invention;

FIG. 3J is a cross-sectional view schematically illustrating a method for manufacturing a wiring substrate according to an embodiment of the present invention;

FIG. 3K is a cross-sectional view schematically illustrating a method for manufacturing a wiring substrate according to an embodiment of the present invention;

FIG. 4 is a cross-sectional view schematically illustrating a wiring substrate of a first modified example according to an embodiment of the present invention;

FIG. 5A is a cross-sectional view schematically illustrating a method for manufacturing a wiring substrate of a second modified example according to an embodiment of the present invention;

FIG. 5B is a cross-sectional view schematically illustrating the method for manufacturing the wiring substrate of the second modified example according to an embodiment of the present invention;

FIG. 5C is a cross-sectional view schematically illustrating the method for manufacturing the wiring substrate of the second modified example according to an embodiment of the present invention; and

FIG. 5D is a cross-sectional view schematically illustrating the method for manufacturing the wiring substrate of the second modified example according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

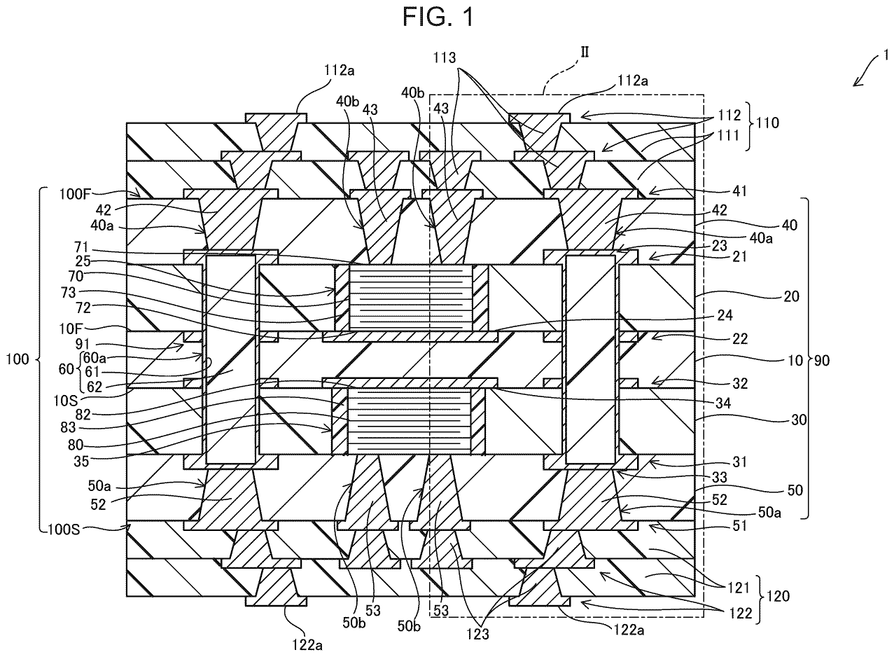

FIG. 1 is a cross-sectional view illustrating a wiring substrate 1 according to an embodiment of the present invention. As illustrated in FIG. 1, the wiring substrate 1 includes a multilayer core substrate 100, a first build-up layer 110, and a second build-up layer 120. The first build-up layer 110 is formed on a first surface (100F) of the multilayer core substrate 100. The second build-up layer 120 is formed on a second surface (100S) of the multilayer core substrate 100.

The first build-up layer 110 is constructed by alternately forming insulating layers 111 and conductor layers 112 on the first surface (100F) of the multilayer core substrate 100. The second build-up layer 120 is constructed by alternately forming insulating layers 121 and conductor layers 122 on the second surface (100S) of the multilayer core substrate 100. In the example illustrated in FIG. 1, the first build-up layer 110 is composed of two insulating layers 111 and two conductor layers 112, and the second build-up layer 120 is composed of two insulating layers 121 and two conductor layers 122. In each insulating layer 111, via conductors 113 are formed, connecting the conductor layer on the insulating layer 111 to the conductor layer below the insulating layer 111. In each insulating layer 121, via conductors 123 are formed, connecting the conductor layer on the insulating layer 121 to the conductor layer below the insulating layer 121.

The multilayer core substrate 100 includes a multilayer insulating layer 90, through-hole conductors 91, surface conductor layers (a first surface conductor layer 41 and a second surface conductor layer 51), and connection conductors (first connection conductors 43 and second connection conductors 53). Components (a first component 70 and a second component 80) are accommodated in the multilayer core substrate 100. The multilayer insulating layer 90 includes a central insulating layer 10, a first resin substrate 20, a second resin substrate 30, a first outer insulating layer 40, and a second outer insulating layer 50. The first resin substrate 20 is formed on a first surface (10F) of the central insulating layer 10. The second resin substrate 30 is formed on a second surface (10S) of the central insulating layer 10. The central insulating layer 10 is sandwiched between the first resin substrate 20 and the second resin substrate 30.

A first inner conductor layer 21 is formed on a first surface of the first resin substrate 20, and a first inner conductor layer 22 is formed on a second surface of the first resin substrate 20. In other words, the first inner conductor layer 22 is formed on the central insulating layer 10 side, while the first inner conductor layer 21 is formed on an opposite side with respect to the central insulating layer 10. The first inner conductor layer 21 includes first cover conductors 23. The first inner conductor layer 22 also includes a first component placement conductor layer 24. A second inner conductor layer 31 is formed on a first surface of the second resin substrate 30, and a second inner conductor layer 32 is formed on a second surface of the second resin substrate 30. In other words, the second inner conductor layer 32 is formed on the central insulating layer 10 side, while the second inner conductor layer 31 is formed on an opposite side with respect to the central insulating layer 10. The second inner conductor layer 31 includes second cover conductors 33. The second inner conductor layer 32 also includes a second component placement conductor layer 34. The first inner conductor layer 22 and the second inner conductor layer 32 may or may not be embedded in the central insulating layer 10.

A first opening 25 penetrating the first resin substrate 20 is formed in the first resin substrate 20. The first opening 25 exposes the first component placement conductor layer 24. The first component 70 is accommodated in the first opening 25. The first component 70 is an electronic component. For example, the first component 70 is a capacitor. The first component 70 may also be an inductor, IVR, or the like. In other embodiments, multiple first components 70 may be accommodated in the first opening 25. The first component 70 has a first electrode surface 71 and a first non-electrode surface 72 on an opposite side with respect to the first electrode surface 71. The first non-electrode surface 72 of the first component 70 is positioned on the first component placement conductor layer 24 exposed from the first opening 25. That is, the first non-electrode surface 72 of the first component 70 is positioned on the first surface (10F) of the central insulating layer 10 exposed from the first opening 25. The first electrode surface 71 of the first component 70 faces the first outer insulating layer 40. The first electrode surface 71 is connected to the first connection conductors 43 of the first outer insulating layer 40. A gap between an inner surface of the first opening 25 and the first component 70 is filled with a first embedding resin 73. The first embedding resin 73 is, for example, a thermosetting resin. The first embedding resin 73 may also be a photocurable resin. The first embedding resin 73 is provided separately from the first resin substrate 20 and the first outer insulating layer 40.

A second opening 35 penetrating the second resin substrate 30 is formed in the second resin substrate 30. The second opening 35 exposes the second component placement conductor layer 34. The second component 80 is accommodated in the second opening 35. The second component 80 is an electronic component. The second component 80 is similar to the first component 70. In other embodiments, multiple second components 80 may be accommodated in the second opening 35. The second component 80 has a second electrode surface 81 and a second non-electrode surface 82 on an opposite side with respect to the second electrode surface 81. The second non-electrode surface 82 of the second component 80 is positioned on the second component placement conductor layer 34 exposed from the second opening 35. That is, the second non-electrode surface 82 of the second component 80 is positioned on the second surface (10S) of the central insulating layer 10 exposed from the second opening 35. The second electrode surface 81 of the second component 80 faces the second outer insulating layer 50. The second electrode surface 81 is connected to the second connection conductors 53 of the second outer insulating layer 50. A gap between an inner surface of the second opening 35 and the second component 80 is filled with a second embedding resin 83. The second embedding resin 83 is, for example, a thermosetting resin. The second embedding resin 83 may also be a photocurable resin. The second embedding resin 83 is provided separately from the second resin substrate 30 and the second outer insulating layer 50.

In the embodiment, the second opening 35 and the second component 80 are provided at positions that overlap with the first opening 25 and the first component 70 in the thickness direction of the wiring substrate 1. In other embodiments, it is also possible that the second opening 35 and the second component 80 are provided at positions that do not overlap with the first opening 25 and the first component 70 in the thickness direction of the wiring substrate 1.

The first outer insulating layer 40 is formed on the first resin substrate 20. The first surface conductor layer 41 is formed on a first surface of the first outer insulating layer 40. The first connection conductors 43 are formed in the first outer insulating layer 40. The first connection conductors 43 are formed in holes (40b) that penetrate the first outer insulating layer 40 and expose the first electrode surface 71 of the first component 70. The first connection conductors 43 connect the first surface conductor layer 41 to the first electrode surface 71 of the first component 70.

The second outer insulating layer 50 is formed on the second resin substrate 30. The second surface conductor layer 51 is formed on a second surface of the second outer insulating layer 50. The second connection conductors 53 are formed in the second outer insulating layer 50. The second connection conductors 53 are formed in holes (50b) that penetrate the second outer insulating layer 50 and expose the second electrode surface 81 of the second component 80. The second connection conductors 53 connect the second surface conductor layer 51 to the second electrode surface 81 of the second component 80.

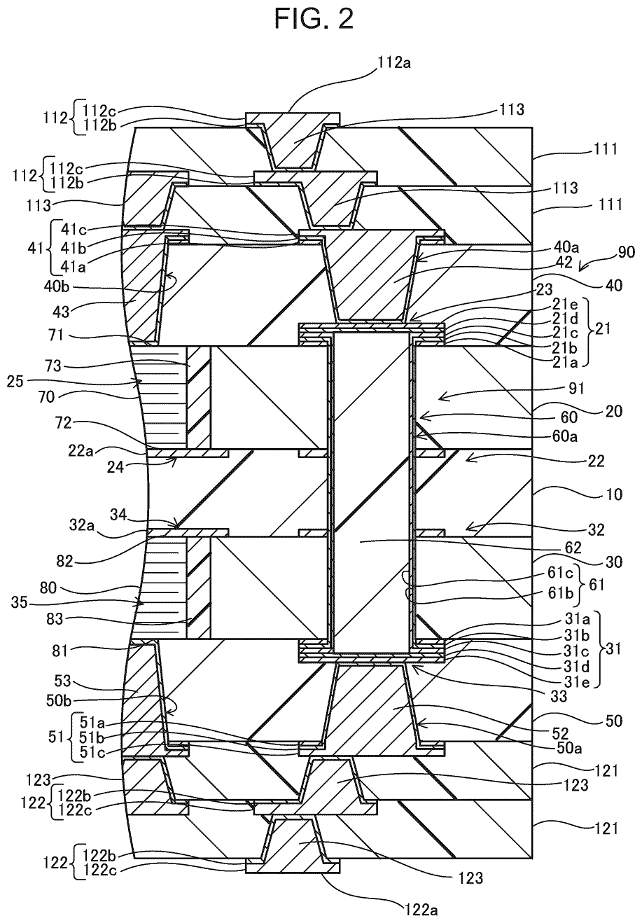

In the wiring substrate 1, the first inner conductor layers (21, 22), the first surface conductor layer 41, the second inner conductor layers (31, 32), the second surface conductor layer 51, the conductor layers 112 in the first build-up layer 110, and the conductor layers 122 in the second build-up layer 120 can have any conductor patterns. In FIG. 1, these conductor layers are simplified for clarity and are illustrated as each having a single-layer structure. However, as will be described in detail below with reference to FIG. 2, these conductor layers may each have a multilayer structure including 2 or more layers.

The inner conductor layers, namely the first inner conductor layer 21 and the second inner conductor layer 31, are formed in through holes 60 of the multilayer core substrate 100. By forming the inner conductor layers in the through holes 60, the multilayer core substrate 100 is penetrated, enabling stable signal transmission. In this case, the inner conductor layers are not limited in size, thickness, material, and the like. The first inner conductor layer 21 and the second inner conductor layer 31 may be formed as inner conductor layers, or either the first inner conductor layer 21 or the second inner conductor layer 31 alone may be formed as an inner conductor layer. Forming both the first inner conductor layer 21 and the second inner conductor layer 31 as the inner conductor layers facilitates ensuring stable signal transmission. Further, forming the first inner conductor layer 21 and the second inner conductor layer 31 ensures the strength of the multilayer core substrate 100.

In the description of the wiring substrate 1 of the present embodiment, a side farther from the central insulating layer 10 in a thickness direction of the wiring substrate 1 is also referred to as an “upper side” or simply “upper”, and a side closer to the central insulating layer 10 is also referred to as a “lower side” or simply “lower”. Further, for each of the conductor layers and the insulating layers, a surface facing an opposite side with respect to the central insulating layer 10 is also referred to as an “upper surface”, and a surface facing the central insulating layer 10 is also referred to as a “lower surface”. Therefore, for example, in the description of the first build-up layer 110 and the second build-up layer 120, a side farther from the multilayer core substrate 100 is also referred to as an “upper side”, or simply “upper”, and a side closer to the multilayer core substrate 100 is also referred to as a “lower side”, or simply “lower”. Further, in the description of the wiring substrate 1 of the present embodiment, for each of the conductor layers and the insulating layers, the terms “first surface” and “second surface” may be used. In this case, the first surface is described as an upper surface merely for convenience, and it may be either an upper surface or a lower surface.

The insulating layers and resin substrates constituting the multilayer insulating layer 90 according to an embodiment of the present invention are each formed by impregnating a core material, which serves as a reinforcing material, with an insulating resin and curing it. As the insulating resin, epoxy resin, bismaleimide triazine resin (BT resin), or phenol resin can be used. Examples of the reinforcing material include glass fiber, aramid fiber, glass nonwoven fabric, aramid nonwoven fabric, and the like. By containing a core material in each of the insulating layers and resin substrates, a wiring substrate 1 with high rigidity and suppressed warpage can be provided. On the other hand, the insulating layers 111 and insulating layers 121 used as build-up layers are preferably formed of an insulating resin that does not contain a core material. This is because an insulating resin that does not contain a core material is suitable for via formation. Further, the insulating layers may each contain an inorganic filler such as silica.

Each through-hole conductor 91 includes a through hole 60, a first via conductor 42, and a second via conductor 52. The through-hole conductors 91 connect the first surface conductor layer 41 and the second surface conductor layer 51.

Each through hole 60 includes an inner wall conductor layer 61 formed on an inner wall of a through hole (60a) and a filler 62 that fills the through hole (60a). The inner wall conductor layer 61 is formed on the inner wall of the through hole (60a) that penetrates the first resin substrate 20, the central insulating layer 10, and the second resin substrate 30. The filler 62 fills the through hole (60a). At an end part of each through hole 60 on the first resin substrate 20 side, a first cover conductor 23 connected to the inner wall conductor layer 61 is formed. The first cover conductor 23 covers an end part of the filler 62 on the first resin substrate 20 side. At an end part of each through hole 60 on the second resin substrate 30 side, a second cover conductor 33 connected to the inner wall conductor layer 61 is formed. The second cover conductor 33 covers an end part of the filler 62 on the second resin substrate 30 side.

Each first via conductor 42 is formed in a hole (40a) that penetrates the first outer insulating layer 40 and exposes a first cover conductor 23. The first via conductors 42 connect the first surface conductor layer 41 and the first cover conductors 23. Each second via conductor 52 is formed in a hole (50a) that penetrates the second outer insulating layer 50 and exposes a second cover conductor 33. The second via conductors 52 connect the second surface conductor layer 51 and the second cover conductors 33.

On the multilayer core substrate 100 of the wiring substrate 1, the first build-up layer 110 and the second build-up layer 120 are formed. The first build-up layer 110 is formed on the first surface (100F) of the multilayer core substrate 100. The second build-up layer 120 is formed on the second surface (100S) of the multilayer core substrate 100. In the illustrated example, the first build-up layer 110 and the second build-up layer 120 each include two conductor layers and two insulating layers. However, the first build-up layer 110 and the second build-up layer 120 may each include three or more conductor layers and three or more insulating layers, or may each include only one conductor layer and one insulating layer.

The conductor layer 112 that is on the surface side in the first build-up layer 110 and is positioned as an outermost layer of the wiring substrate 1, and the conductor layer 122 that is on the surface side in the second build-up layer 120 and is positioned as an outermost layer of the wiring substrate 1, include connection pads (112a, 122a) used for mounting an external electronic component, a motherboard (not illustrated), or the like. When an electronic component is mounted, bumps (not illustrated) made of any metal, such as solder, copper, or tin, are formed on the connection pads (112a, 122a).

With reference to FIG. 2, structures of the conductors included in the wiring substrate 1 are described in detail. FIG. 2 illustrates an enlarged view of a portion (II) of FIG. 1.

As illustrated in FIG. 2, the first inner conductor layer 22 is formed by a metal foil (22a) formed on the lower surface (second surface) of the first resin substrate 20. In the first inner conductor layer 22, the first component placement conductor layer 24 is formed. The second inner conductor layer 32 is formed by a metal foil (32a) formed on the upper surface (first surface) of the second resin substrate 30. In the second inner conductor layer 32, the second component placement conductor layer 34 is formed. The first inner conductor layer 22 and the second inner conductor layer 32 each have a single-layer structure including the metal foil (22a) or the metal foil (32a), but may each have a multilayer structure including two or more layers. The type of metal in the metal foils (22a, 32a) is not particularly limited, but it is preferable to use one having copper as a main component.

Here, the conductor layers according to an embodiment of the present invention are each formed by any combination of a metal foil layer, a seed layer, and an electrolytic plating layer. The metal foil layer is a conductor layer formed by patterning a metal foil formed on an insulating layer. The type of metal in the metal foil is not particularly limited, but it is preferable to use one having copper as a main component. The seed layer is a conductor layer formed by patterning a seed film, such as an electroless plating film or a sputtered film, formed over an entire surface of a substrate. The type of metal in the seed film is not particularly limited, but it is preferable to use one having copper, nickel, or titanium as a main component. The electrolytic plating layer is a conductor layer formed by patterning a resist on a seed film formed on a substrate and patterning an electrolytic plating film deposited in a region where the resist is not formed. The type of metal in the electrolytic plating film is not particularly limited, but it is preferable to use one having copper as a main component.

On the other hand, the first inner conductor layer 21 is formed by a metal foil layer (21a) formed on the upper surface (first surface) of the first resin substrate 20, a seed layer (21b) on the metal foil layer (21a), an electrolytic plating layer (21c) on the seed layer (21b), a seed layer (21d) on the electrolytic plating layer (21c), and an electrolytic plating layer (21e) on the seed layer (21d). The first inner conductor layer 21 has a five-layer structure including the metal foil layer (21a), the seed layer (21b), the electrolytic plating layer (21c), the seed layer (21d), and the electrolytic plating layer (21e). Further, each first cover conductor 23 is formed by the seed layer (21d) and the electrolytic plating layer (21e). Similarly, the second inner conductor layer 31 is formed by a metal foil layer (31a) formed on the upper surface (first surface) of the second resin substrate 30, a seed layer (31b) on the metal foil layer (31a), an electrolytic plating layer (31c) on the seed layer (31b), a seed layer (31d) on the electrolytic plating layer (31c), and an electrolytic plating layer (31e) on the seed layer (31d). The second inner conductor layer 31 has a five-layer structure including the metal foil layer (31a), the seed layer (31b), the electrolytic plating layer (31c), the seed layer (31d), and the electrolytic plating layer (31e). Further, each second cover conductor 33 is formed by the seed layer (31d) and the electrolytic plating layer (31e).

The inner wall conductor layer 61 of each through hole 60 is formed by a seed layer (61b) formed on an inner wall surface of the through hole (60a) and an electrolytic plating layer (61c) on the seed layer (61b). The seed layer (61b) is common to the seed layers (21b, 31b) and is formed simultaneously with the seed layers (21b, 31b). The electrolytic plating layer (61c) is common to the electrolytic plating layers (21c, 31c) and is formed simultaneously with the electrolytic plating layers (21c, 31c). Each through hole 60 is filled with the filler 62. The filler 62 is formed using an insulating material containing a resin such as epoxy, acrylic, or phenol. Alternatively, the filler 62 may be a solidified conductive paste or conductive ink containing conductive particles such as silver particles. By filling each through hole 60 with the filler 62, a via conductor can be formed directly above the through hole 60. The first cover conductor 23 and the second cover conductor 33 are respectively formed on end surfaces of the filler so as to cover the end surfaces of the filler 62.

The first surface conductor layer 41 is formed by a metal foil layer (41a) formed on the upper surface (first surface) of the first outer insulating layer 40, a seed layer (41b) on the metal foil layer (41a), and an electrolytic plating layer (41c) on the seed layer (41b).

The first surface conductor layer 41 has a three-layer structure including the metal foil layer (41a), the seed layer (41b), and the electrolytic plating layer (41c). Similarly, the second surface conductor layer 51 is formed by a metal foil layer (51a) formed on the upper surface of the second outer insulating layer 50, a seed layer (51b) on the metal foil layer (51a), and an electrolytic plating layer (51c) on the seed layer (51b). The second surface conductor layer 51 has a three-layer structure including the metal foil layer (51a), the seed layer (51b), and electrolytic plating layer (51c).

Each first via conductor 42 is formed in a hole (40a) that penetrates the first outer insulating layer 40 and exposes a first cover conductor 23. The first via conductor 42 is formed by a seed layer (41b) formed on an inner wall surface of the hole (40a) and on the first cover conductor 23, and an electrolytic plating layer (41c) formed on the seed layer (41b) and filling the hole (40a). The seed layer (41b) and electrolytic plating layer (41c) forming the first via conductor 42 are common to the seed layer (41b) and electrolytic plating layer (41c) forming the first surface conductor layer 41. The first surface conductor layer 41 and the first via conductor 42 are formed simultaneously. Similarly, each second via conductor 52 is formed in a hole (50a) that penetrates the second outer insulating layer 50 and exposes a second cover conductor 33. The second via conductor 52 is formed by a seed layer (51b) formed on an inner wall surface of the hole (50a) and on the second cover conductor 33, and an electrolytic plating layer (51c) formed on the seed layer (51b) and filling the hole (50a). The seed layer (51b) and electrolytic plating layer (51c) forming the second via conductor 52 are common to the seed layer (51b) and electrolytic plating layer (51c) forming the second surface conductor layer 51. The second surface conductor layer 51 and the second via conductor 52 are formed simultaneously.

The first connection conductors 43 are formed in the holes (40b) that penetrate the first outer insulating layer 40 and expose the first electrode surface 71 of the first component 70. Each first connection conductor 43 is formed by a seed layer (41b) formed on an inner wall surface of a hole (40b) and on the first electrode surface 71, and an electrolytic plating layer (41c) formed on the seed layer (41b) and filling the hole (40b). The seed layer (41b) and electrolytic plating layer (41c) forming the first connection conductors 43 are common to the seed layer (41b) and electrolytic plating layer (41c) forming the first surface conductor layer 41 and the first via conductors 42. The first surface conductor layer 41, the first via conductors 42, and the first connection conductors 43 are formed simultaneously.

Similarly, the second connection conductors 53 are formed in the holes (50b) that penetrate the second outer insulating layer 50 and expose the second electrode surface 81 of the second component 80. Each second connection conductor 53 is formed by a seed layer (51b) formed on an inner wall surface of a hole (50b) and on the second electrode surface 81, and an electrolytic plating layer (51c) formed on the seed layer (51b) and filling the hole (50b). The seed layer (51b) and electrolytic plating layer (51c) forming the second connection conductors 53 are common to the seed layer (51b) and electrolytic plating layer (51c) forming the second surface conductor layer 51 and the second via conductors 52. The second surface conductor layer 51, the second via conductors 52, and the second connection conductors 53 are formed simultaneously.

The conductor layers (112, 122) in the first build-up layer 110 and the second build-up layer 120 are formed without using a metal foil. Each conductor layer 112 is formed by a seed layer (112b) and an electrolytic plating layer (112c). Similarly, each conductor layer 122 is formed by a seed layer (122b) and an electrolytic plating layer (122c).

Each via conductor 113 in the first build-up layer 110 is formed by a seed layer (112b) and an electrolytic plating layer (112c). The seed layer (112b) and electrolytic plating layer (112c) of the via conductor 113 are common to the seed layer (112b) and electrolytic plating layer (112c) of the conductor layer 112. Similarly, each via conductor 123 in the second build-up layer 120 is formed by a seed layer (122b) and an electrolytic plating layer (122c). The seed layer (122b) and electrolytic plating layer (122c) of the via conductor 123 are common to the seed layer (122b) and electrolytic plating layer (122c) of the conductor layer 122.

### Method for Manufacturing Wiring Substrate

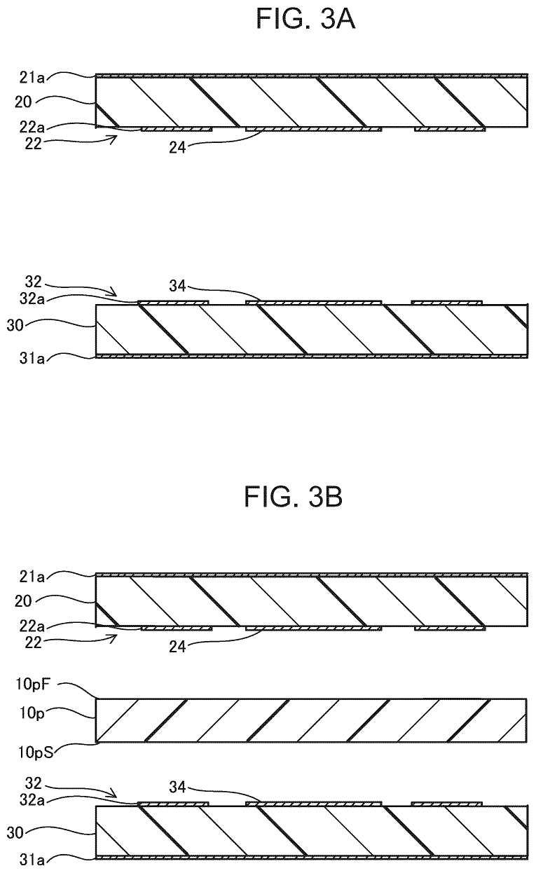

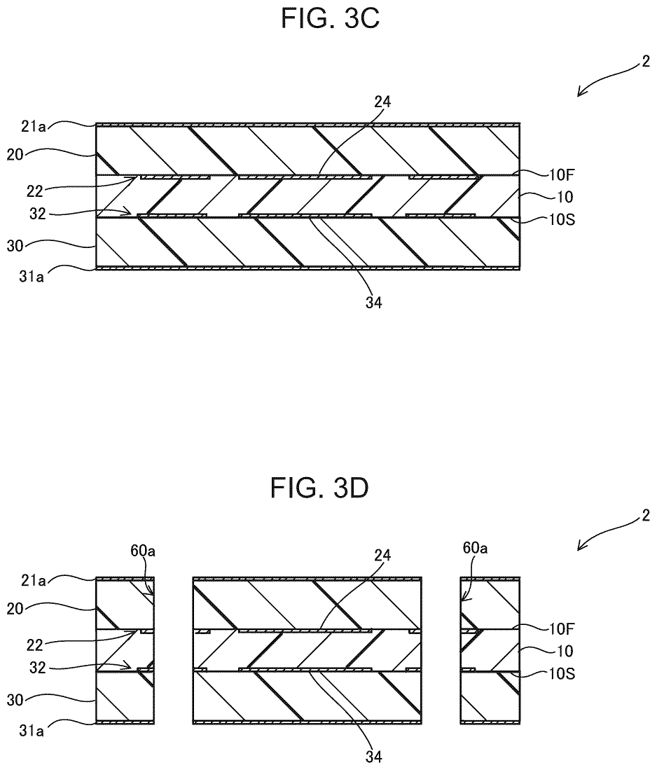

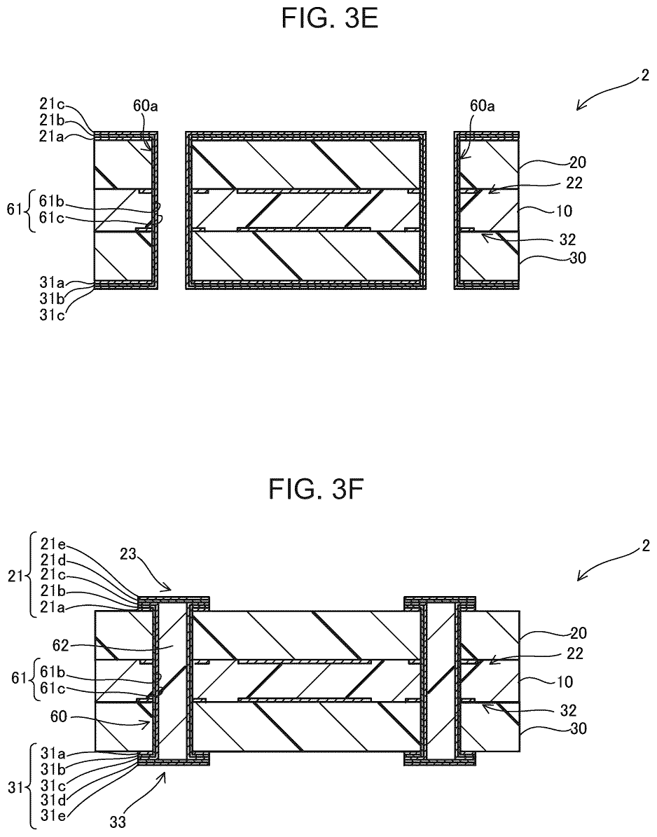

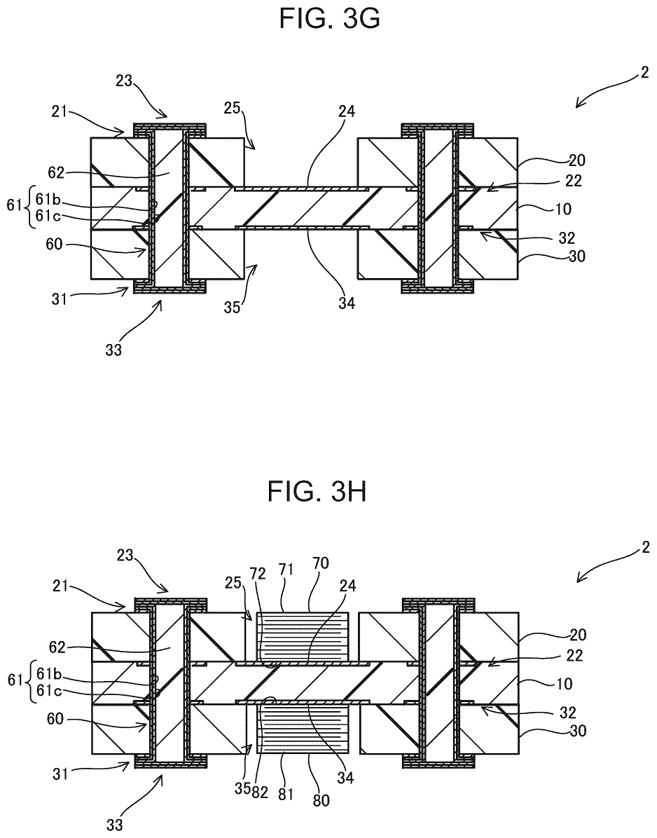

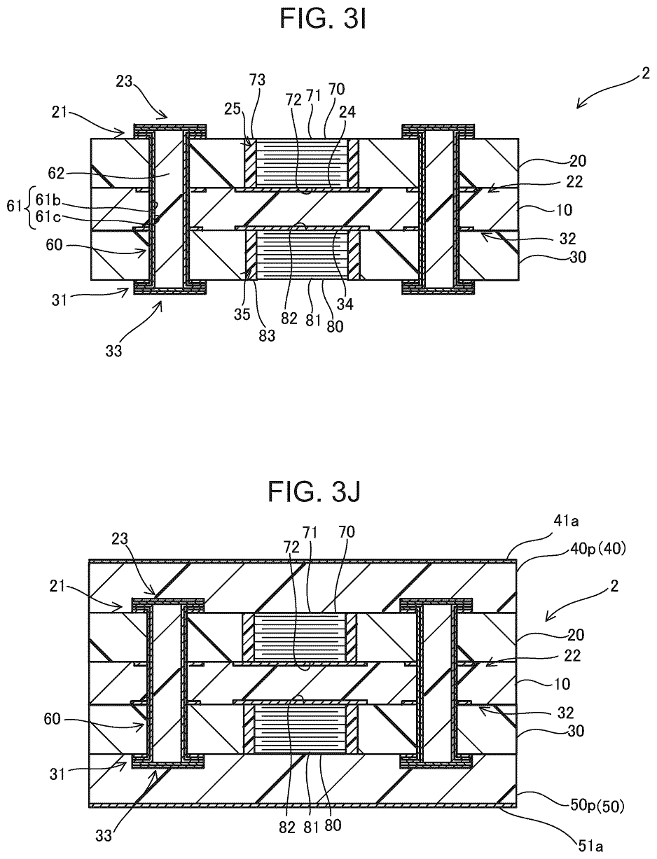

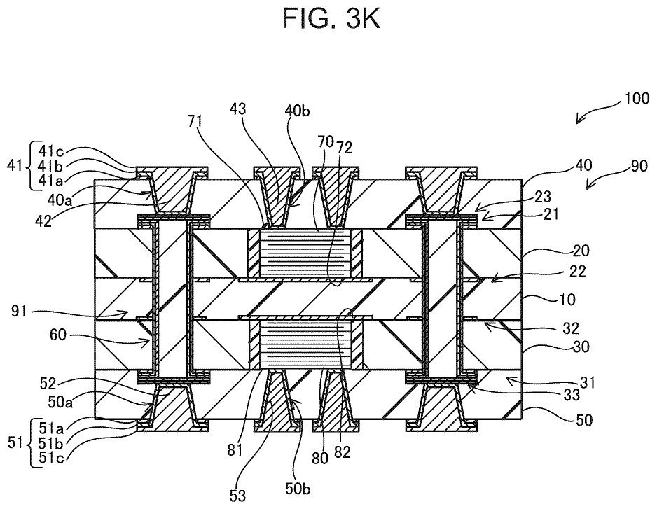

FIGS. 3A-3K illustrate a method for manufacturing the wiring substrate 1 according to an embodiment of the present invention. FIGS. 3A-3K are cross-sectional views. As illustrated in FIG. 3A, the first resin substrate 20 is prepared with the metal foil (21a) formed on the upper surface (first surface) and the first inner conductor layer 22 formed on the lower surface (second surface). The first resin substrate 20 is formed using a double-sided copper-clad laminate, in which metal foils (21a, 22a) are respectively formed on both surfaces of a resin substrate containing a core material, as a starting material. The first inner conductor layer 22 having desired conductor patterns is formed using a subtractive method that involves subjecting the metal foil (22a) to etching using a mask in which wirings are drawn. The first inner conductor layer 22 also includes the first component placement conductor layer 24. Similarly, the second resin substrate 30 is prepared with the metal foil (31a) formed on the upper surface (first surface) and the second inner conductor layer 32 formed on the lower surface (second surface). The second inner conductor layer 32 also includes the second component placement conductor layer 34.

As illustrated in FIG. 3B, the first resin substrate 20, a prepreg (10p) that will become the central insulating layer 10 upon curing, and the second resin substrate 30 are formed. Specifically, the first resin substrate 20 is formed on a first surface (10pF) side of the prepreg (10p) that will become the central insulating layer 10, and the second resin substrate 30 is formed on a second surface (10pS) side of the prepreg (10p). The first inner conductor layer 22 faces the first surface (10pF). The second inner conductor layer 32 faces the second surface (10pS).

The first resin substrate 20, the prepreg (10p), and the second resin substrate 30 are collectively hot-pressed. As illustrated in FIG. 3C, the prepreg (10p) is cured to form the central insulating layer 10. The first inner conductor layer 22 after the pressing is embedded in the first surface (10F) of the central insulating layer 10. The second inner conductor layer 32 is embedded in the second surface (10S) of the central insulating layer 10. As a result, an intermediate substrate 2 is formed, which includes the central insulating layer 10, the first resin substrate 20, and the second resin substrate 30. During the collective hot pressing, pressure applied to a central portion in a pressing direction is concentrated and absorbed by the prepreg (10p), and thus, uniformity in its thickness can be satisfactorily ensured. That is, there is little risk of losing the parallelism between the first resin substrate 20 and the second resin substrate 30, and a multilayer core substrate 100 with good flatness can be obtained.

In this case, for convenience of description, the first resin substrate 20 and the second resin substrate 30 are assumed to be the same in thickness. However, it is also possible that the first resin substrate 20 and the second resin substrate 30 differ in thickness. Specifically, the first resin substrate 20, in which the first component 70 is accommodated, is made thinner than the second resin substrate 30, in which the second component 80 is accommodated. This allows a first component 70 with a smaller thickness to be accommodated. Conversely, the first resin substrate 20, in which the first component 70 is accommodated, is made thicker than the second resin substrate 30, in which the second component 80 is accommodated. This allows a first component 70 with a larger thickness to be accommodated.

As illustrated in FIG. 3D, the through holes (60a) are formed, penetrating the metal foil (21a), the first resin substrate 20, the first inner conductor layer 22, the central insulating layer 10, the second inner conductor layer 32, the second resin substrate 30, and the metal foil (31a). The through holes (60a) are formed, for example, by drilling with a cutting device such as a drill. The through holes (60a) may also be formed by laser irradiation.

As illustrated in FIG. 3E, a seed layer (21b) is formed on the metal foil layer (21a). A seed layer (61b) is formed on an inner wall of each of the through holes (60a). A seed layer (31b) is formed on the metal foil layer (31a). The seed layers (21b, 31b, 61b) are formed, for example, as seed films by electroless plating or sputtering. Electrolytic plating films are respectively formed using the seed films as power feeding layers. Electrolytic plating layers (21c, 31c, 61c) are respectively formed on the seed films. After that, an inner wall conductor layer 61 is formed by the seed layer (61b) and the electrolytic plating layer (61c) through pattern formation.

A cavity of each of the through holes (60a) is filled with a filler 62. For example, a resin such as epoxy, acrylic, or phenol is injected from one or both ends of a through hole. The filler 62 may be formed, for example, by filling each through hole (60a) with a conductive paste containing conductive particles, such as silver particles, instead of an insulating resin such as epoxy resin. The insulating resin, such as epoxy resin, or the conductive paste, used for the filler 62 is solidified, by heating or the like when necessary, to form the filler 62. Each through hole 60 is formed by the inner wall conductor layer 61 and the filler 62 in a through hole (60a). End surfaces of the filler 62 after solidification may be polished, when necessary, using any method such as chemical polishing or mechanical polishing. By this polishing, the end surfaces of the filler 62 are preferably respectively made substantially flush with the surfaces of the electrolytic plating layers (21c, 31c).

Further, seed layers (21d, 31d) and electrolytic plating layers (21e, 31e) are sequentially formed on the electrolytic plating layers (21c, 31c) and the filler 62. The seed layers (21d, 31d) and electrolytic plating layers (21e, 31e) are formed, for example, in the same manner as the seed layers (21b, 31b) and electrolytic plating layers (21c, 31c). On the first resin substrate 20, a five-layer structure is formed, including the metal foil layer (21a), the seed layer (21b), the electrolytic plating layer (21c), the seed layer (21d), and the electrolytic plating layer (21e). On the second resin substrate 30, a five-layer structure is formed, including the metal foil layer (31a), the seed layer (31b), the electrolytic plating layer (31c), the seed layer (31d), and the electrolytic plating layer (31e). After that, as illustrated in FIG. 3F, the first inner conductor layer 21 and the second inner conductor layer 31, each having desired conductor patterns, are formed using a subtractive method involving etching using a mask in which wirings are drawn. Simultaneously, the first cover conductors 23 are formed by the seed layer (21d) and electrolytic plating layer (21e) on the ends of the fillers 62 on the first resin substrate 20 side. The second cover conductors 33 are formed by the seed layer (31d) and electrolytic plating layer (31e) on the ends of the fillers 62 on the second resin substrate 30 side.

As illustrated in FIG. 3G, the first opening 25 penetrating the first resin substrate 20 is formed in a region of the first resin substrate 20 where the first component 70 is to be accommodated. The first opening 25 is formed, for example, by laser irradiation. The laser irradiation removes the resin of the first resin substrate 20 but does not remove the first component placement conductor layer 24. Therefore, the first component placement conductor layer 24 is exposed at a bottom surface of the first opening 25. Similarly, the second opening 35 penetrating the second resin substrate 30 is formed in a region of the second resin substrate 30 where the second component 80 is to be accommodated. The second component placement conductor layer 34 is exposed at a bottom surface of the second opening 35.

As illustrated in FIG. 3H, the first component 70 is accommodated in the first opening 25. The first non-electrode surface 72 of the first component 70 is positioned on the first component placement conductor layer 24 exposed from the first opening 25. In this case, by providing an adhesive layer between the first non-electrode surface 72 of the first component 70 and the first component placement conductor layer 24, the first component 70 is fixed onto the first component placement conductor layer 24. The first electrode surface 71 of the first component 70 is flush with the upper surface of the first resin substrate 20. It is also possible that the first electrode surface 71 of the first component 70 is below the upper surface of the first resin substrate 20. Similarly, the second component 80 is accommodated in the second opening 35. The second non-electrode surface 82 of the second component 80 is positioned on the second component placement conductor layer 34 exposed from the second opening 35. By providing an adhesive layer between the second non-electrode surface 82 of the second component 80 and the second component placement conductor layer 34, the second component 80 is fixed onto the second component placement conductor layer 34. The second electrode surface 81 of the second component 80 is flush with the upper surface of the second resin substrate 30. It is also possible that the second electrode surface 81 of the second component 80 is below the upper surface of the second resin substrate 30.

As illustrated in FIG. 3I, the gap between the inner surface of the first opening 25 of the first resin substrate 20 and the first component 70 is filled with the first embedding resin 73. Similarly, the gap between the inner surface of the second opening 35 of the second resin substrate 30 and the second component 80 is filled with the second embedding resin 83. The first embedding resin 73 and the second embedding resin 83 are preferably a thermosetting resin or a photocurable resin. The first embedding resin 73 and the second embedding resin 83 are cured. The first component 70 is fixed in the first opening 25. The second component 80 is fixed in the second opening 35.

As illustrated in FIG. 3J, the first outer insulating layer 40, made of a prepreg (40p), is formed on the first inner conductor layer 21. In this case, a metal foil (41a) is formed on the first outer insulating layer 40. The second outer insulating layer 50, made of a prepreg (50p), is formed on the second inner conductor layer 31. A metal foil (51a) is formed on the second outer insulating layer 50. The metal foil (41a), the first outer insulating layer 40, the intermediate substrate 2, the second outer insulating layer 50, and the metal foil (51a) are collectively hot-pressed. The prepreg (40p) is cured to form the first outer insulating layer 40. The prepreg (50p) is cured to form the second outer insulating layer 50.

In the first outer insulating layer 40, the holes (40a) are formed, penetrating the metal foil (41a) and the insulating layer of the first outer insulating layer 40, respectively exposing the first cover conductors 23. Further, the holes (40b) are formed, penetrating the metal foil (41a) and the insulating layer of the first outer insulating layer 40, exposing the first electrode surface 71 of the first component 70. In the second outer insulating layer 50, the holes (50a) are formed, penetrating the insulating layer of the second outer insulating layer 50, respectively exposing the second cover conductors 33. Further, the holes (50b) are formed, penetrating the metal foil (51a) and the insulating layer of the second outer insulating layer 50, exposing the second electrode surface 81 of the second component 80. In this case, hole openings are formed, for example, using laser such as CO₂ laser. A seed film is formed on the metal foil (41a), inner surfaces of the holes (40a), and inner surfaces of the holes (40b) by electroless plating or sputtering. Further, a seed film is formed on the metal foil (51a) and inner surfaces of the holes (50b). An electrolytic plating film is formed on each seed film using the seed film as a power feeding layer. The electrolytic plating film fills the holes (40a, 40b, 50a, 50b). After that, as illustrated in FIG. 3K, the first surface conductor layer 41 including a seed layer (41b) and an electrolytic plating layer (41c), and the second surface conductor layer 51 including a seed layer (51b) and an electrolytic plating layer (51c), each having desired conductor patterns, are formed using a subtractive method involving etching using a mask in which wirings are drawn. Simultaneously, the first via conductors 42, the first connection conductors 43, the second via conductors 52, and the second connection conductors 53 are formed. The first surface conductor layer 41, the first via conductors 42, the first connection conductors 43, the second surface conductor layer 51, the second via conductors 52, and the second connection conductors 53 may also be formed using a modified semi-additive method (MSAP) using the metal foils (41a, 51a). The multilayer insulating layer 90 is formed, including the central insulating layer 10, the first resin substrate 20, the second resin substrate 30, the first outer insulating layer 40, and the second outer insulating layer 50. The through-hole conductors 91 are formed, each including a first via conductor 42, a through hole 60, and a second via conductor 52. The multilayer core substrate 100 is formed, including the multilayer insulating layer 90, the first surface conductor layer 41, the second surface conductor layer 51, and the through-hole conductors 91.

The insulating layers (111, 121) and the conductor layers (112, 122) are alternately formed on both sides of the multilayer core substrate 100. The first build-up layer 110 is formed on the first surface (100F) of the multilayer core substrate 100. The second build-up layer 120 is formed on the second surface (100S) of the multilayer core substrate 100. For example, a film-like insulating resin (for example, epoxy resin) without a reinforcing material is thermocompression bonded to the first surface (100F) and the second surface (100S), forming the insulating layer 111 on the first surface (100F) side among the two insulating layers 111 and the insulating layer 121 on the second surface (100S) side among the two insulating layers 121. Through holes are formed, for example, using CO₂ laser at locations where the via conductors 113 or the via conductors 123 are to be formed in the insulating layer 111 or the insulating layer 121. A seed film made of a conductor, such as copper, is formed on inner walls of the through holes and on surfaces of the insulating layers (111, 121), for example, by electroless plating or sputtering. A plating resist having openings for forming a conductor layer is formed, and an electrolytic plating film is formed in the openings by electrolytic plating using the seed film as a power feeding layer. Through resist stripping and etching, a conductor layer 112 and a conductor layer 122, as well as via conductors 113 and via conductors 123, each including a seed layer and an electrolytic plating layer, are formed. In other words, the conductor layer 112 on the first surface (100F) side among the two conductor layers 112 and the conductor layer 122 on the second surface (100S) side among the two conductor layers 122 are formed using a semi-additive method (SAP) without using a metal foil. Along with the conductor layers (112, 122), the via conductors 113 penetrating the insulating layer 111 on the first surface (100F) side and the via conductors 123 penetrating the insulating layer 121 on the second surface (100S) side are formed.

Further, the insulating layer 111 and insulating layer 121 on the surface-layer sides are formed in the same manner as the insulating layer 111 on the first surface (100F) side and the insulating layer 121 on the second surface (100S) side. Further, the conductor layers (112, 122) on the surface-layer sides are formed in the same manner as the conductor layer 112 on the first surface (100F) side and the conductor layer 122 on the second surface (100S) side. Further, the via conductors (113, 123) penetrating the respective insulating layers (111, 121) on the surface-layer sides are formed in the same manner as the via conductor 113 penetrating the insulating layer 111 on the first surface (100F) side and the via conductor 123 penetrating the insulating layer 121 on the second surface (100S) side. In this way, the first build-up layer 110 and the second build-up layer 120 are formed. As a result, the wiring substrate 1 (FIG. 1) of the embodiment is obtained.

In the wiring substrate 1 of the embodiment, the first opening 25 accommodating the first component 70 penetrates the first resin substrate 20. The second opening 35 accommodating the second component 80 penetrates the second resin substrate 30. The first opening 25 and the second opening 35 do not penetrate the multilayer core substrate 100. This reduces the amount of the first embedding resin 73 needed to fill the gap between the inner surface of the first opening 25 and the first component 70, as well as the amount of the second embedding resin 83 needed to fill the gap between the inner surface of the second opening 35 and the second component 80. Further, in the wiring substrate 1 of the embodiment, the through holes 60 penetrate the first resin substrate 20, the central insulating layer 10, and the second resin substrate 30. The through holes 60 each have a shorter length than those in a conventional wiring substrate. Stability during signal transmission is ensured.

### First Modified Example

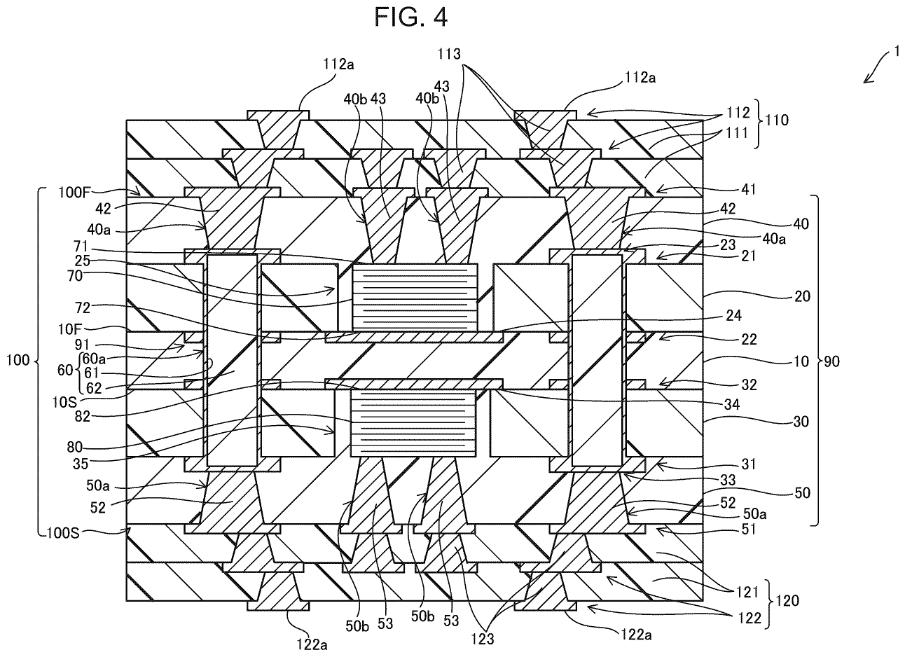

FIG. 4 is a cross-sectional view illustrating a wiring substrate 1 of a first modified example. As illustrated in FIG. 4, in a first modified example, the gap between the inner surface of the first opening 25 and the first component 70 is filled with a part of the first outer insulating layer 40. The embedding resin that fills the gap between the inner surface of the first opening 25 and the first component 70 is a part of the first outer insulating layer 40. Similarly, the gap between the inner surface of the second opening 35 and the second component 80 is filled with a part of the second outer insulating layer 50. The embedding resin that fills the gap between the inner surface of the second opening 35 and the second component 80 is a part of the second outer insulating layer 50.

A method for manufacturing the wiring substrate 1 in the first modified example is substantially the same as that of the embodiment. However, in the first modified example, as illustrated in FIG. 3H, after the component 70 is accommodated in the opening 25 and the second component 80 is accommodated in the second opening 35, the prepreg (40p) that will become the first outer insulating layer 40 is formed on the first inner conductor layer 21. The metal foil (41a) is formed on the prepreg (40p). The prepreg (50p) that will become the second outer insulating layer 50 is formed on the second inner conductor layer 31. The metal foil (51a) is formed on the prepreg (50p). The metal foil (41a), the prepreg (40p), the intermediate substrate 2, the prepreg (50p), and the metal foil (51a) are collectively hot-pressed. In this case, a part of the prepreg (40p) flows into and fills the gap between the inner surface of the first opening 25 and the first component 70. Similarly, a part of the prepreg (50p) flows into and fills the gap between the inner surface of the second opening 35 and the second component 80. The prepreg (40p) is cured to form the first outer insulating layer 40. The prepreg (50p) is cured to form the second outer insulating layer 50. The gap between the inner surface of the first opening 25 and the first component 70 is filled with a part of the first outer insulating layer 40. The first component 70 is fixed in the first opening 25. The gap between the inner surface of the second opening 35 and the second component 80 is filled with a part of the second outer insulating layer 50. The second component 80 is fixed in the second opening 35. After that, in the same manner as the manufacturing method of the embodiment, the first surface conductor layer 41, the first via conductors 42, the first connection conductors 43, the second surface conductor layer 51, the second via conductors 52, and the second connection conductors 53 are formed. Subsequent processes are the same as in the manufacturing method of the embodiment. The multilayer insulating layer 90 is formed. The through-hole conductors 91 are formed, each including a first via conductor 42, a through hole 60, and a second via conductor 52. The multilayer core substrate 100 is formed, including the multilayer insulating layer 90, the first surface conductor layer 41, the second surface conductor layer 51, and the through-hole conductors 91. The first build-up layer 110 and the second build-up layer 120 are formed. The wiring substrate 1 of the first modified example (FIG. 4) is obtained.

### Second Modified Example

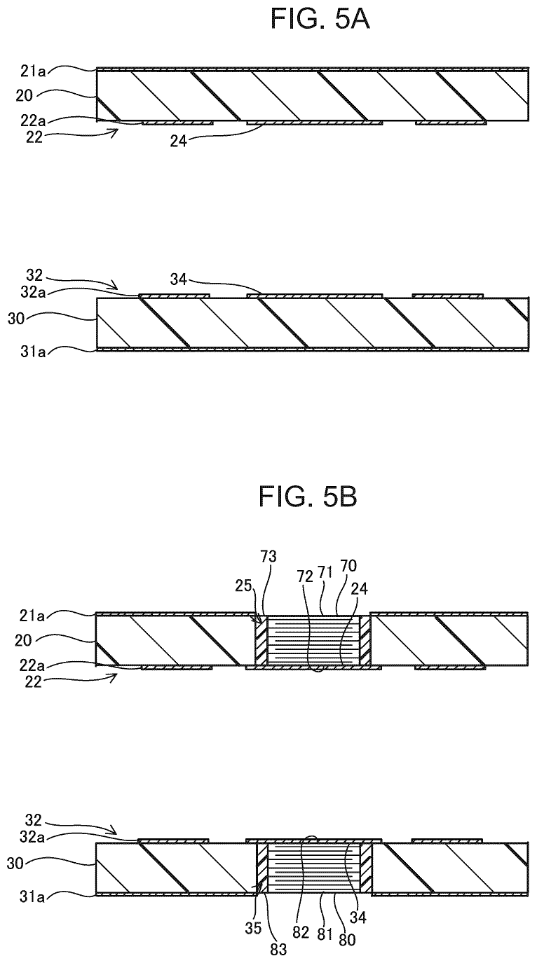

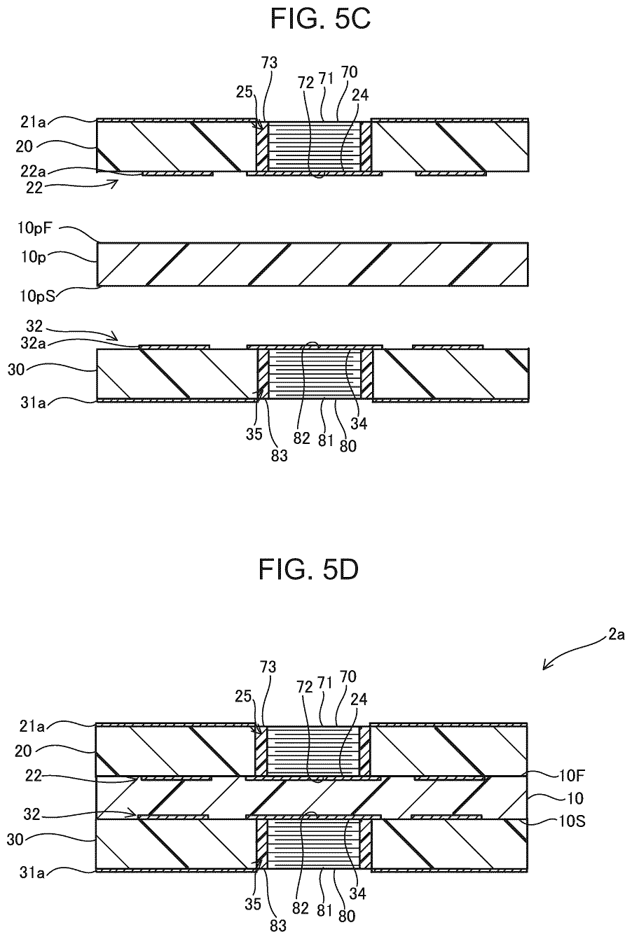

A wiring substrate 1 of a second modified example is the same as the wiring substrate 1 of the embodiment. In the second modified example, the method for manufacturing the wiring substrate 1 differs from that of the embodiment. In the second modified example, the first component 70 and the second component 80 are accommodated before an intermediate substrate (2a) (see FIG. 5D) is manufactured. The method for manufacturing the wiring substrate 1 of the second modified example is illustrated in FIGS. 5A to 5D. FIGS. 5A to 5D are cross-sectional views.

As illustrated in FIG. 5A, the first resin substrate 20 is prepared with a metal foil (21a) formed on the upper surface (first surface) and the first inner conductor layer 22 formed on the lower surface (second surface). Similarly, the second resin substrate 30 is prepared with the metal foil (31a) formed on the upper surface (first surface) and the second inner conductor layer 32 formed on the lower surface (second surface).

As illustrated in FIG. 5B, the metal foil (21a) in the region of the first resin substrate 20 where the first component 70 is to be accommodated is removed by etching or the like. Similarly, the metal foil (31a) in the region of the second resin substrate 30 where the second component 80 is to be accommodated is removed by etching or the like. The first opening 25 penetrating the first resin substrate 20 is formed in the region of the first resin substrate 20 where the first component 70 is to be accommodated. The first opening 25 is formed, for example, by laser irradiation. The laser irradiation removes the resin of the first resin substrate 20 but does not remove the component placement conductor layer 24. Therefore, the first component placement conductor layer 24 is exposed at a bottom surface of the first opening 25. Similarly, the second opening 35 penetrating the second resin substrate 30 is formed in a region of the second resin substrate 30 where the second component 80 is to be accommodated. The second component placement conductor layer 34 is exposed at a bottom surface of the second opening 35. The first component 70 is positioned in the first opening 25. The first non-electrode surface 72 of the first component 70 is positioned on the first component placement conductor layer 24 exposed from the first opening 25. In this case, by providing an adhesive layer between the first non-electrode surface 72 of the first component 70 and the first component placement conductor layer 24, the first component 70 is fixed onto the first component placement conductor layer 24. The first electrode surface 71 of the first component 70 is flush with the upper surface of the first resin substrate 20. It is also possible that the first electrode surface 71 of the first component 70 is below the upper surface of the first resin substrate 20. Similarly, the second component 80 is positioned in the second opening 35. The second non-electrode surface 82 of the second component 80 is positioned on the second component placement conductor layer 34 exposed from the second opening 35. By providing an adhesive layer between the second non-electrode surface 82 of the second component 80 and the second component placement conductor layer 34, the second component 80 is fixed onto the second component placement conductor layer 34. The second electrode surface 81 of the second component 80 is flush with the upper surface of the second resin substrate 30. It is also possible that the second electrode surface 81 of the second component 80 is below the upper surface of the second resin substrate 30.

Further, the gap between the first opening 25 of the first resin substrate 20 and the first component 70 is filled with the first embedding resin 73. Similarly, the gap between the second opening 35 of the second resin substrate 30 and the second component 80 is filled with the second embedding resin 83. The first embedding resin 73 and the second embedding resin 83 are preferably a thermosetting resin or a photocurable resin. The first embedding resin 73 and the second embedding resin 83 are cured. The first component 70 is fixed in the first opening 25. The second component 80 is fixed in the second opening 35.

As illustrated in FIG. 5C, the first resin substrate 20, the prepreg (10p) that will become the central insulating layer 10 upon curing, and the second resin substrate 30 are formed. Specifically, the first resin substrate 20, which accommodates the first component 70, is formed on the first surface (10pF) side of the prepreg (10p) that will become the central insulating layer 10, and the second resin substrate 30, which accommodates the second component 80, is formed on the second surface (10pS) side of the prepreg (10p). The first inner conductor layer 22 faces the first surface (10pF). The second inner conductor layer 32 faces the second surface (10pS).

As illustrated in FIG. 5D, the first resin substrate 20, the prepreg (10p), and the second resin substrate 30 are collectively hot-pressed. The prepreg (10p) is cured to form the central insulating layer 10. The first inner conductor layer 22 after the pressing is embedded in the first surface (10F) of the central insulating layer 10. The second inner conductor layer 32 is embedded in the second surface (10S) of the central insulating layer 10. As a result, the intermediate substrate (2a) is formed, which includes the central insulating layer 10, the first resin substrate 20, and the second resin substrate 30. During the collective hot pressing, pressure applied to a central portion in a pressing direction is concentrated and absorbed by the prepreg (10p), and thus, uniformity in its thickness can be satisfactorily ensured. That is, there is little risk of losing the parallelism between the first resin substrate 20 and the second resin substrate 30, and a multilayer core substrate 100 with good flatness can be obtained.

After that, in the same manner as the embodiment, the through holes 60 are formed in the intermediate substrate (2a). The first inner conductor layer 21 and the second inner conductor layer 31, each having desired conductor patterns, are formed. The first cover conductors 23 and the second cover conductors 33 are formed (see FIG. 3I).

After that, in the same manner as the embodiment, the first outer insulating layer 40 and the second outer insulating layer 50 are formed (see FIG. 3J). The first surface conductor layer 41, the first via conductors 42, the first connection conductors 43, the second surface conductor layer 51, the second via conductors 52, and the second connection conductors 53 are formed (see FIG. 3K). The multilayer insulating layer 90 is formed, including the central insulating layer 10, the first resin substrate 20, the second resin substrate 30, the first outer insulating layer 40, and the second outer insulating layer 50. The through-hole conductors 91 are formed, each including a first via conductor 42, a through hole 60, and a second via conductor 52. The multilayer core substrate 100 is formed, including the multilayer insulating layer 90, the first surface conductor layer 41, the second surface conductor layer 51, and the through-hole conductors 91.

The first build-up layer 110 is formed on the first surface (100F) of the multilayer core substrate 100. The second build-up layer 120 is formed on the second surface (100S) of the multilayer core substrate 100. As a result, the wiring substrate 1 (FIG. 1) of the embodiment is obtained.

Japanese Patent Application Laid-Open Publication No. 2015-185564 describes a printed wiring board including a multilayer core substrate, an opening extending from a first surface to a second surface of the multilayer core substrate, an electronic component accommodated in the opening, and a build-up layer including an interlayer resin insulating layer formed on the multilayer core substrate. It is also disclosed that the opening in the multilayer core substrate is filled with a resin or the like in a gap between the substrate and the component.

In the printed wiring board of Japanese Patent Application Laid-Open Publication No. 2015-185564, the opening is a through hole extending from the first surface to the second surface of the multilayer core substrate. Therefore, a certain amount of resin is filled into the gap between the substrate and the component in the opening. Further, when the filled resin is insufficient, it may cause problems such as gaps forming in the opening. Conversely, when the filled resin is excessive, it may cover the component, potentially leading to problems with via formation involving the component.

A wiring substrate according to an embodiment of the present invention includes: a multilayer core substrate; and a build-up layer formed by an insulating layer and a conductor layer on the multilayer core substrate. The multilayer core substrate includes a multilayer insulating layer, a through-hole conductor, surface conductor layers, and connection conductors, with components accommodated therein. The multilayer insulating layer includes: a central insulating layer; resin substrates; and outer insulating layers. A first resin substrate is formed on a first surface of the central insulating layer, a first outer insulating layer is formed on the first resin substrate, and a first surface conductor layer is formed on the first outer insulating layer. A second resin substrate is formed on a second surface of the central insulating layer, a second outer insulating layer is formed on the second resin substrate, and a second surface conductor layer is formed on the second outer insulating layer. The through-hole conductor includes: a through hole; a first via conductor; and a second via conductor. The through hole is a hole penetrating the first resin substrate, the central insulating layer, and the second resin substrate, an inner wall conductor layer is formed on an inner wall of the hole, a first cover conductor is formed on the first resin substrate, and a second cover conductor is formed on the second resin substrate. The first via conductor is formed in a hole that penetrates the first outer insulating layer and exposes the first cover conductor, and connects the first surface conductor layer and the first cover conductor. The second via conductor is formed in a hole that penetrates the second outer insulating layer and exposes the second cover conductor, and connects the second surface conductor layer and the second cover conductor. The components include a first component and a second component. The first component has a first electrode surface and a first non-electrode surface on an opposite side with respect to the first electrode surface. The second component has a second electrode surface and a second non-electrode surface on an opposite side with respect to the second electrode surface. A first opening penetrating the first resin substrate is formed, the first non-electrode surface of the first component is positioned on the first surface of the central insulating layer exposed from the first opening, and the first electrode surface is connected to a first connection conductor of the first outer insulating layer. A second opening penetrating the second resin substrate is formed, the second non-electrode surface of the second component is positioned on the second surface of the central insulating layer exposed from the second opening, and the second electrode surface is connected to a second connection conductor of the second outer insulating layer.

In a wiring substrate according to an embodiment of the present invention, the first opening accommodating the first component penetrates the first resin substrate, and the second opening accommodating the second component penetrates the second resin substrate, but neither penetrates the multilayer core substrate. This allows for a reduction in the certain amount of resin needed to fill the gap between the substrate and the first component in the first opening and the gap between the substrate and the second component in the second opening. Further, the through hole penetrates the first resin substrate, the central insulating layer, and the second resin substrate. The through hole is shorter than that in the conventional art, ensuring stable signal transmission in the through hole. Further, by using the multilayer core substrate, it can be applied to embedded components without restrictions on thickness or the like.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a multilayer core substrate;
a build-up layer formed on the multilayer core substrate and comprising an insulating layer and a conductor layer; and
a plurality of components accommodated in the multilayer core substrate and comprising a first component and a second component such that the first component has a first electrode surface and a first non-electrode surface on an opposite side with respect to the first electrode surface and that the second component has a second electrode surface and a second non-electrode surface on an opposite side with respect to the second electrode surface,
wherein the multilayer core substrate includes a central insulating layer, a first resin substrate formed on a first surface of the central insulating layer, a first outer insulating layer formed on the first resin substrate, a first surface conductor layer formed on the first outer insulating layer, a first connection conductor formed in the first outer insulating layer, a second resin substrate formed on a second surface of the central insulating layer, a second outer insulating layer formed on the second resin substrate, a second surface conductor layer formed on the second outer insulating layer, a second connection conductor formed in the second outer insulating layer, and a through-hole conductor formed through the first outer insulating layer, the first resin substrate, the central insulating layer, the second resin substrate and the second outer insulating layer, the through-hole conductor includes a first via conductor formed in the first outer insulating layer and connecting the first surface conductor layer and the first cover conductor, a second via conductor formed in the second outer insulating layer and connecting the second surface conductor layer and the second cover conductor, an inner wall conductor layer formed on an inner wall of a through hole penetrating through the first resin substrate, the central insulating layer and the second resin substrate, a first cover conductor formed on the first resin substrate, and a second cover conductor formed on the second resin substrate, and the plurality of components is positioned such that the first non-electrode surface of the first component is positioned on the first surface of the central insulating layer, the first electrode surface of the first component is connected to the first connection conductor in the first outer insulating layer, the second non-electrode surface of the second component is positioned on the second surface of the central insulating layer, and the second electrode surface of the second component is connected to the second connection conductor of the second outer insulating layer.

2. The wiring substrate according to claim 1, wherein the plurality of components is formed such that the first electrode surface of the first component is positioned on a same plane as an end of the through hole on a first resin substrate side and that the second electrode surface of the second component is positioned on a same plane as an end part of the through hole on a second resin substrate side.

3. The wiring substrate according to claim 1, wherein the multilayer core substrate includes a first embedding resin filling a gap formed between the first component and an inner surface of a first opening accommodating the first component, and a second embedding resin filling a gap formed between the second component and an inner surface of a second opening accommodating the second component.

4. The wiring substrate according to claim 3, wherein the multilayer core substrate is formed such that the first embedding resin is a part of the first outer insulating layer and that the second embedding resin is a part of the second outer insulating layer.

5. The wiring substrate according to claim 1, wherein the multilayer core substrate includes a filler filling the through hole and comprising a resin.

6. The wiring substrate according to claim 1, wherein the multilayer core substrate is formed such that each of the central insulating layer, the first resin substrate, the second resin substrate, the first outer insulating layer and the second outer insulating layer includes a core material.

7. The wiring substrate according to claim 1, wherein the multilayer core substrate includes an inner conductor layer formed in the through hole of the multilayer core substrate.

8. The wiring substrate according to claim 7, wherein the multilayer core substrate is formed such that the inner conductor layer includes a first inner conductor layer and a second inner conductor layer and that the first inner conductor layer is formed on a central insulating layer side of the first resin substrate and/or the second inner conductor layer is formed on a central insulating layer side of the second resin substrate.

9. The wiring substrate according to claim 8, wherein the first inner conductor layer or the second inner conductor layer is embedded in the central insulating layer.

10. The wiring substrate according to claim 8, wherein the first inner conductor layer includes a first component placement conductor circuit corresponding to a region in which the first component is positioned, and the second inner conductor layer includes a second component placement conductor circuit corresponding to a region in which the second component is positioned.

11. The wiring substrate according to claim 2, wherein the multilayer core substrate includes a first embedding resin filling a gap formed between the first component and an inner surface of a first opening accommodating the first component, and a second embedding resin filling a gap formed between the second component and an inner surface of a second opening accommodating the second component.

12. The wiring substrate according to claim 11, wherein the multilayer core substrate is formed such that the first embedding resin is a part of the first outer insulating layer and that the second embedding resin is a part of the second outer insulating layer.

13. The wiring substrate according to claim 2, wherein the multilayer core substrate includes a filler filling the through hole and comprising a resin.

14. The wiring substrate according to claim 2, wherein the multilayer core substrate is formed such that each of the central insulating layer, the first resin substrate, the second resin substrate, the first outer insulating layer and the second outer insulating layer includes a core material.

15. The wiring substrate according to claim 2, wherein the multilayer core substrate includes an inner conductor layer formed in the through hole of the multilayer core substrate.

16. The wiring substrate according to claim 15, wherein the multilayer core substrate is formed such that the inner conductor layer includes a first inner conductor layer and a second inner conductor layer and that the first inner conductor layer is formed on a central insulating layer side of the first resin substrate and/or the second inner conductor layer is formed on a central insulating layer side of the second resin substrate.

17. The wiring substrate according to claim 16, wherein the first inner conductor layer or the second inner conductor layer is embedded in the central insulating layer.

18. The wiring substrate according to claim 16, wherein the first inner conductor layer includes a first component placement conductor circuit corresponding to a region in which the first component is positioned, and the second inner conductor layer includes a second component placement conductor circuit corresponding to a region in which the second component is positioned.

19. The wiring substrate according to claim 7, wherein the multilayer core substrate is formed such that the inner conductor layer includes a first inner conductor layer and a second inner conductor layer and that the first inner conductor layer is formed on a central insulating layer side of the first resin substrate or the second inner conductor layer is formed on a central insulating layer side of the second resin substrate.

20. The wiring substrate according to claim 7, wherein the multilayer core substrate is formed such that the inner conductor layer includes a first inner conductor layer and a second inner conductor layer and that the first inner conductor layer is formed on a central insulating layer side of the first resin substrate and the second inner conductor layer is formed on a central insulating layer side of the second resin substrate.
